(19) United States
(12) Patent Application Publication
(10) Pub. No.: US 2026/0040476 A1
(43) Pub. Date: Feb. 5, 2026

(54) COMPONENT MOUNTING STRUCTURE

(71) Applicant: TDK CORPORATION, Tokyo (JP)

(72) Inventors: Sanehito KEMMOTSU, Tokyo (JP); Kouji Kaneko, Tokyo (JP); Mitsuyoshi Takao, Tokyo (JP); Hiroshi Kameyama, Tokyo (JP); Shinya Motooka, Tokyo (JP); Junpei Sawayama, Tokyo (JP)

(73) Assignee: TDK CORPORATION, Tokyo (JP)

(21) Appl. No.: 19/288,699

(22) Filed: Aug. 1, 2025

(30) Foreign Application Priority Data
Aug. 2, 2024 (JP) 2024-126644

(51) Int. Cl. H05K 7/14

(52) U.S. Cl. CPC H05K 7/1432

(57) ABSTRACT

A slit is provided between a first pressing portion and a second pressing portion, and the slit extends to and reaches at least a step portion. Therefore, a transmission path of the displacement between the first pressing portion and the second pressing portion is divided by the slit. Therefore, the slit can suppress interference of a displacement generated when one of the pressing portions presses one of the components with the other pressing portion. Therefore, a sufficient pressing force can be obtained in each of the first and second pressing portions without increasing the distance between the components or dividing the pressing member.

### CROSS-REFERENCE TO RELATED APPLICATIONS

This application is based upon and claims the benefit of priority from Japanese Patent Applications No. 2024-126644, filed on 2 Aug. 2024, the entire content of which is incorporated herein by reference.

### TECHNICAL FIELD

The present disclosure relates to a component mounting structure.

### BACKGROUND

Known in the art is a structure in which a component provided in a housing is supported by a pressing member, as a component mounting structure (for example, Japanese Patent Application No. Publication 2016-63200). In this component mounting structure, a plurality of components are pressed by a plurality of pressing portions provided in one support portion, respectively.

### SUMMARY

In the component mounting structure described above, when the components are arranged close to each other, the pressing portions are also close to each other. In this case, due to the influence of displacement caused by the stress when one of the pressing portions presses one of the components, it is likely to reduce the pressing force of the other pressing portion against the other component. When the components are arranged to be separated from each other or the pressing member is divided into a plurality of pressing members, it is likely to increase the size of the product increases and/or the number of parts.

According to an aspect of the present disclosure, there is provided a component mounting structure capable of suppressing an increase in the size of the product and sufficiently pressing a plurality of components with a small number of parts.

A component mounting structure according to an aspect of the present disclosure includes a housing, a first component disposed in the housing and a second component adjacent to the first component, and a pressing member pressing the first component and the second component toward the housing. The pressing member includes a support portion fixed to the housing, a step portion extending from the support portion in a first direction toward a side opposite the housing, an edge portion extending from an end of the step portion on the side opposite the housing in a second direction intersecting the first direction, a first pressing portion pressing the first component and a second pressing portion pressing the second component, the first pressing portion and the second pressing portion protruding from the edge portions. A slit is provided between the first pressing portion and the second pressing portion, and the slit extends at least to the step portion.

In the component mounting structure according to an aspect of the present disclosure, the pressing member includes a support portion fixed to the housing, a step portion extending from the support portion in a first direction toward a side opposite the housing, an edge portion extending from an end of the step portion on the side opposite the housing in a second direction intersecting the first direction, a first pressing portion pressing the first component and a second pressing portion pressing the second component, the first pressing portion and the second pressing portion protruding from the edge portions. Accordingly, the pressing member may support the first component and the second component by one member. Here, the slit is provided between the first pressing portion and the second pressing portion, and the slit reaches at least the step portion. Therefore, the transmission path of the displacement between the first pressing portion and the second pressing portion is divided by the slit reaching the step portion. Accordingly, the slit can prevent the displacement generated when one pressing portion presses one component from interfering with the other pressing portion. Therefore, a sufficient pressing force can be obtained at each pressing portion without increasing the distance between the first component and the second component or dividing the pressing member. As described above, it is possible to suppress an increase in the size of a product and to sufficiently press a plurality of components with a small number of parts.

The slit may extend in the first direction to the support portion side beyond a central position of the step portion. In this case, a half region of the step portion in the first direction is divided by the slit. Therefore, the transmission path of the displacement between the first pressing portion and the second pressing portion can be further reduced.

The slit may extend to a boundary portion between the step portion and the support portion. In this case, the entire region in the first direction of the step portion is divided by the slit. Therefore, the transmission path of the displacement between the first pressing portion and the second pressing portion can be further reduced.

The slit may extend to the support portion. In this case, the entire region in the first direction of the step portion and the boundary portion are divided by the slit. Therefore, the transmission path of the displacement between the first pressing portion and the second pressing portion can be further reduced.

The support portion may be fixed to the housing via the fixing portion. In this case, the elastic deformation at each of the first pressing portion and the second pressing portion may easily occur.

The first pressing portion and the second pressing portion may be arranged in a third direction, at least part of the slit may be disposed at the same position as the fixing portion in the third direction. In the vicinity of the fixing portion, it is difficult to transmit the displacement between the first pressing portion and the second pressing portion. Therefore, by bringing the slit and the fixing portion closer to each other, the transmission path of the displacement between the first pressing portion and the second pressing portion can be further reduced.

The first pressing portion and the second pressing portion may be arranged in a third direction, at least part of the slit may be disposed at the same position as a gap between the first component and the second component in the third direction. Since any pressing portion cannot be provided at the position of the gap, a sufficient space for arranging the pressing portions can be secured by arranging the slit near the gap. Accordingly, each of the components can be supported by each of the pressing portions in a well-balanced manner.

A component mounting structure according to an aspect of the present disclosure includes a housing, a first component disposed in the housing and a second component adjacent to the first component, and a pressing member pressing the first component and the second component toward the housing. The pressing member includes a support portion fixed to the housing, a step portion extending from the support portion in a first direction toward a side opposite the housing, a first pressing portion pressing the first component and a second pressing portion pressing the second component, the first pressing portion and the second pressing portion extending from an end of the step portion on the side opposite the housing in a second direction intersecting the first direction. A slit is provided between the first pressing portion and the second pressing portion, and the slit extends in the first direction to the support portion side beyond a central position of the step portion.

In the component mounting structure according to an aspect of the present disclosure, the pressing member includes a support portion fixed to the housing, a step portion extending from the support portion in a first direction toward a side opposite the housing, a first pressing portion pressing the first component and a second pressing portion pressing the second component, the first pressing portion and the second pressing portion extending from an end of the step portion on the side opposite the housing in a second direction intersecting the first direction. Accordingly, the pressing member may support the first component and the second component by one member. Here, the slit is provided between the first pressing portion and the second pressing portion, and the slit reaches the support side from the central position of the step portion in the first direction. Therefore, the transmission path of the displacement between the first pressing portion and the second pressing portion is divided by the slit reaching the support side rather than the central position of the step portion. Accordingly, the slit can prevent the displacement generated when one pressing portion presses one component from interfering with the other pressing portion. Therefore, a sufficient pressing force can be obtained at each pressing portion without increasing the distance between the first component and the second component or dividing the pressing member. As described above, it is possible to suppress an increase in the size of a product and to sufficiently press a plurality of components with a small number of parts.

### BRIEF DESCRIPTION OF THE DRAWINGS

FIG. 1 is a side view of a power supply device including a component mounting structure according to one embodiment of the present disclosure.

FIG. 2 is a perspective view of the component mounting structure according to the present embodiment of the present disclosure.

FIG. 3 is a perspective view of the component mounting structure according to the present embodiment of the present disclosure.

FIG. 4 is a plan view of the component mounting structure.

FIG. 5 is a cross-sectional view taken along line V-V in FIG. 4.

FIG. 6 is a perspective view of the pressing member.

FIGS. 7A and 7B are plan views of the modified pressing member used in the component mounting structure.

FIGS. 8A and 8B are plan views of the modified pressing member used in the component mounting structure.

### DETAILED DESCRIPTION

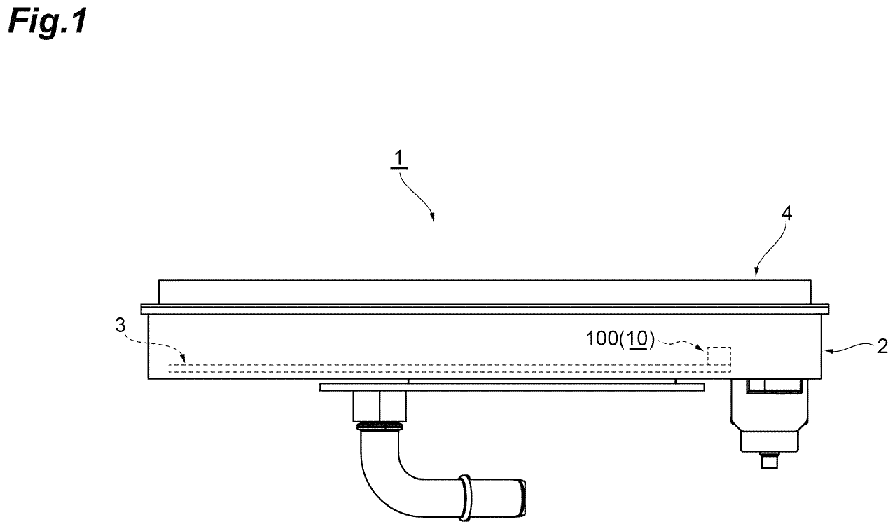

With reference to FIG. 1, a power supply device 1 including a component mounting structure 100 according to the present embodiment is described. FIG. 1 is a side view of the power supply device 1 including the component mounting structure 100. As shown in FIG. 1, the power supply device 1 includes a base plate 2 (a housing), a substrate 3, and a lid body 4. The power supply device 1 is assembled by fitting the lid body 4 onto the base plate 2 in a state where the substrate 3 is housed. The base plate 2 may be made of a die-cast alloy or the like. The power supply device 1 may be a unit including, for example, an AC/DC power supply or a DC/DC converter. The component mounting structure 100 is provided in the power supply device 1. The overall shape of the power supply device 1 is not limited to that shown in FIG. 1. The position of the component mounting structure 100 in the power supply device 1 is not particularly limited.

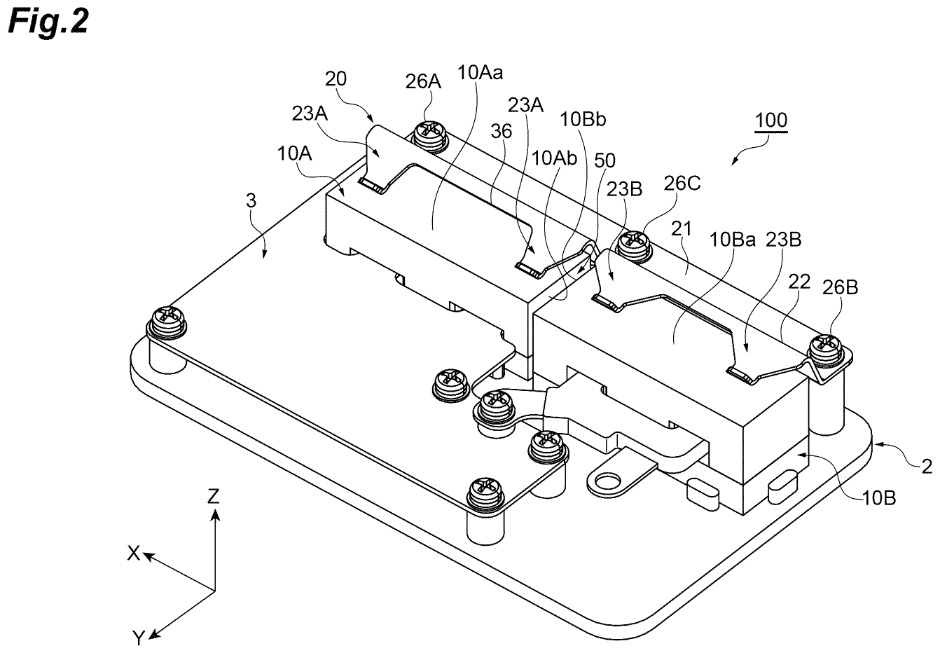

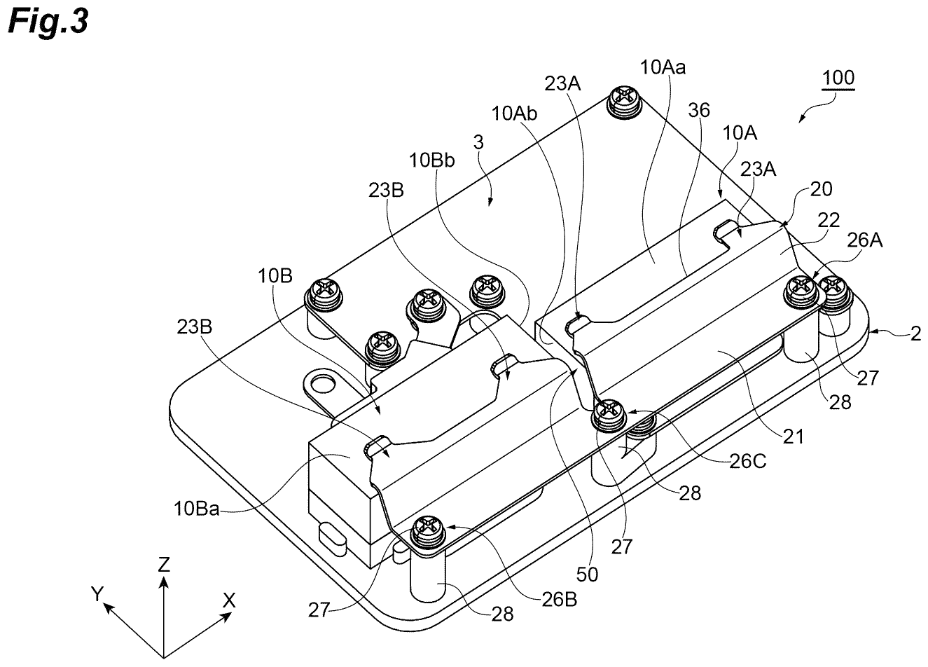

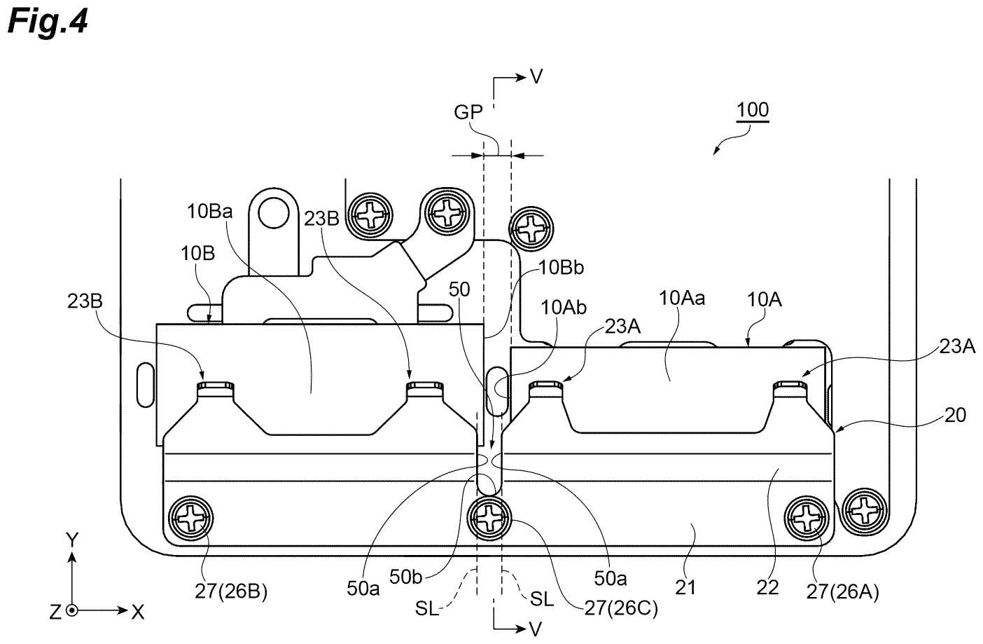

With reference to FIGS. 2 to 4, the structure of the component mounting structure 100 is described. FIGS. 2 and 3 are perspective views of the component mounting structure 100 according to the embodiment of the present disclosure. FIG. 4 is a plan view of the component mounting structure 100. The X-axis direction and the Y-axis direction are set and shown with respect to the bottom surface of the base plate 2 and the direction in which the substrate 3 (see FIG. 1) extends. The Z-axis direction is set to the bottom surface of the base plate 2 and the thickness direction of the substrate 3. In the present specification, the upper side is defined as the positive side in the Z-axis direction, and the lower side is defined as the negative side in the Z-axis direction. In the present specification, for convenience of description, words such as “up” and “down” may be used, but these do not limit the posture of the power supply device 1 and the component mounting structure 100 during use. As shown in FIGS. 2 to 4, the component mounting structure 100 includes the base plate 2, the substrate 3, a first component 10A, a second component 10B, and a pressing member 20.

The first component 10A and the second component 10B are components arranged in the base plate 2. The first component 10A is mounted on the substrate 3. In the present embodiment, cores made of magnetic material and provided for coils are shown as the components 10A and 10B. The components 10A and 10B are configured as a rectangular parallelepiped member having a longitudinal direction in the X-axis direction. Each of the components 10A and 10B has an upper surface 10Aa, 10Ba parallel to the XY plane at a position higher than the bottom surface of the base plate 2 and the substrate 3.

The components 10A and 10B are arranged adjacent to each other in the X-axis direction. The second component 10B is arranged adjacent to the first component 10A on the negative side in the X-axis direction. An end surface 10Ab on the negative side in the X-axis direction of the first component 10A and an end surface 10Bb on the positive side in the X-axis direction of the second component 10B face each other in a state of being separated from each other in the X-axis direction. A gap GP is formed between the first component 10A and the second component 10B (see FIG. 4). The base plate 2 is provided with ribs for positioning the components 10A and 10B, bosses for fastening the substrate 3 with bolts, and the like. The movement of the components 10A and 10B in the XY-axis direction is restricted by the rib or the like of the base plate 2 in addition to being pressed by the pressing member 20.

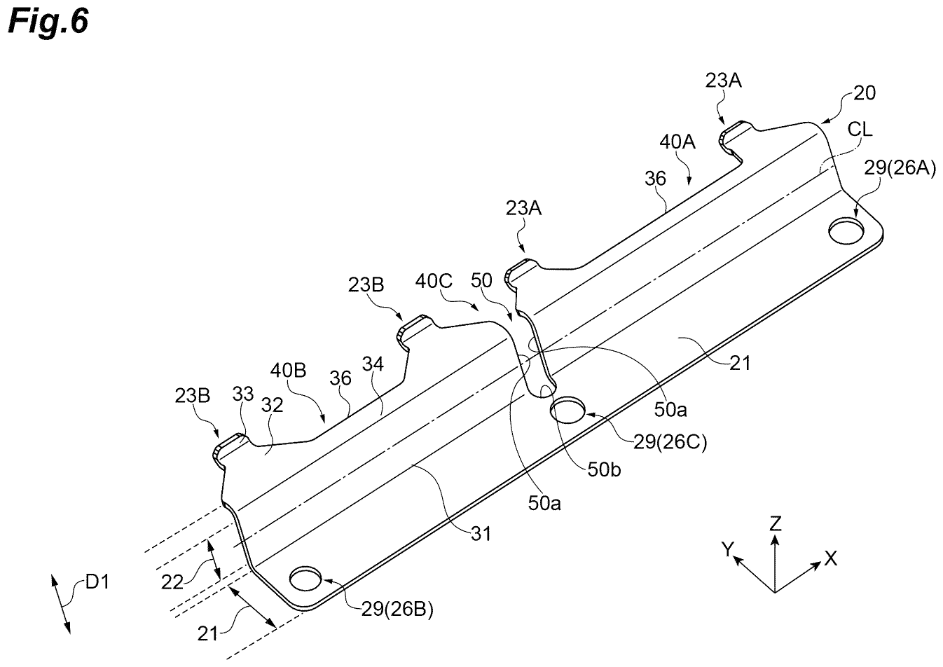

The pressing member 20 is a member for pressing the first component 10A and the second component 10B to the lower side (the housing side). The pressing member 20 includes a support portion 21, a step portion 22, an edge 36, a first pressing portion 23A, and a second pressing portion 23B. In the present embodiment, the pressing member 20 is a member in which the elements 21 22, 23A, and 23B are integrally formed by cutting and bending one metal plate. Accordingly, the pressing member 20 is configured as a single sheet-metal member (see FIG. 6). The pressing member 20 may not necessarily be formed only by bending a single metal plate, and may be formed by joining a plurality of metal plates by a joining method such as welding. In the present embodiment, the pressing member 20 may be arranged on the negative side in the Y-axis direction with respect to the components 10A and 10B.

The support portion 21 is the part that supports the step portion 22 and the pressing portions 23A and 23B and is fixed on the base plate 2. The support portion 21 has a flat plate shape parallel to the X-Y plane and extends in the X-axis direction. The step portion 22 is a portion that rises from the support portion 21 toward the upper side (opposite side to the housing), and has a flat plate shape that rises so as to be inclined with respect to the X-Y plane. The end portions of the support portion 21 and the step portion 22 on the positive side in the X-axis direction are arranged at positions near the end portion of the first component 10A on the positive side in the X-axis direction. The end portions of the support portion 21 and the step portion 22 on the negative side in the X-axis direction is arranged at a position near the end portion of the second component 10B on the negative side in the X-axis direction. The edge 36 extends from the end portion of the upper side (opposite side to the housing) of the step portion 22 toward the components 10A and 10B. The configuration of the edge 36 will be described later.

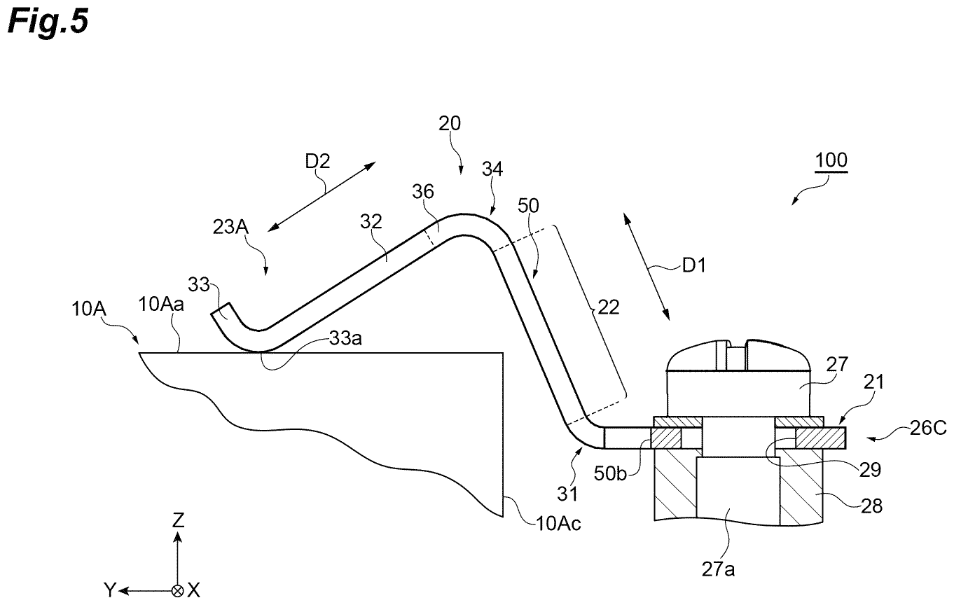

The support portion 21 is fixed on the base plate 2 through fixing portions 26A, 26B, and 26C. The fixing portion 26A is provided near the end portion of the support portion 21 on the positive side in the X-axis direction. The fixing portion 26B is provided near the end portion of the support portion 21 on the negative side in the X-axis direction. The fixing portion 26C is provided near the central position of the support portion 21 in the X-axis direction. Each of the fixing portion 26A, 26B, and 26C is configured by a fastening structure with a bolt 27 and a boss 28 provided in the base plate 2 (see FIG. 3). The support portion 21 includes through holes 29 (see FIG. 6) into which the shaft portion 27a (see FIG. 5) of the bolt 27 of each of the fixing portions 26A, 26B, and 26C are inserted.

The first pressing portion 23A is a part that protrudes from the edge 36 toward the first component 10A and presses the first component 10A. The second pressing portion 23B is a part that protrudes from the edge 36 toward the second component 10B and presses the second component 10B. The first pressing portion 23A and the second pressing portion 23B extend from the edge 36 so as to be inclined toward the positive side in the Y-axis direction and the lower side. In addition, the first pressing portion 23A and the second pressing portion 23B press the upper surface 10Aa of the first component 10A and the upper surface 10Ba of the second component 10B downward.

In the present embodiment, the pressing member 20 includes two of the first pressing portions 23A and two of the second pressing portions 23B. Two of the first pressing portions 23A are arranged at positions spaced apart from each other in the X-axis direction. Two of the first pressing portions 23A portions press the vicinity of the end portion on the positive side in the X-axis direction and the vicinity of the end portion on the negative side in the X-axis direction of the first component 10A. Two of the second pressing portions 23B are arranged at positions spaced apart from each other in the X-axis direction. Two of the second pressing portions 23B press the vicinity of the end portion on the positive side in the X-axis direction and the vicinity of the end portion on the negative side in the X-axis direction of the second component 10B. The first pressing portion 23A on the negative side in the X-axis direction and the second pressing portion 23B on the positive side in the X-axis direction are adjacent to each other in a state of being separated from each other in the X-axis direction. A slit 50 is provided between the first pressing portion 23A and the second pressing portion 23B. In the present embodiment, the slit 50 is provided between the first pressing portion 23A on the negative side in the X-axis direction and the second pressing portion 23B on the positive side in the X-axis direction.

Next, with reference to FIGS. 5 and 6, the configuration of the pressing member 20 will be described in more detail. FIG. 5 is a cross-sectional view taken along line V-V shown in FIG. 4. FIG. 6 is a perspective view of the pressing member 20. In FIG. 5, the fixing portion 26C and the first pressing portion 23A on the negative side in the X-axis direction are shown, the other fixing portions 26A and 26B and the other pressing portions 23A and 23B have the same configuration. As shown in FIG. 5, the support portion 21 is arranged below the upper surface 10Aa of the first component 10A. The support portion 21 is arranged at a position separated to the negative side in the Y-axis direction from a side surface 10Ac on the negative side in the Y-axis direction of the first component 10A. The step portion 22 extends along a first direction D1 from the end portion of the support portion 21 on the positive side in the Y-axis direction. The first direction D1 is a direction inclined with respect to the Z-axis direction so as to be directed upward toward the positive side in the Y-axis direction. The inclination angle of the first direction D1 with respect to the Z-axis direction is not particularly limited, and may be parallel to the Z-axis direction. A boundary portion 31 of the support portion 21 and the step portion 22 is curved with a rounded corner R so that the lower side becomes the outer peripheral side. The curvature radius of the boundary portion 31 is not particularly limited and can be changed as appropriate. The curved boundary portion 31 is an intermediate position between the support portion 21 and the step portion 22, and is a region that does not belong to either the support portion 21 or the step portion 22.

The step portion 22 extends above the upper surface 10Aa of the first component 10A. The first pressing portion 23A includes a first portion 32 and a second portion 33. The edge 36 extends from the upper end portion of the step portion 22 to a second direction D2 intersecting the first direction D1. In addition, the first portion 32 is protruded from the edge 36 to the second direction D2. The second direction D2 is a direction inclined with respect to the Z-axis direction so as to be directed downward toward the positive side in the Y-axis direction. The inclination angle of the second direction D2 with respect to the Z-axis direction is not particularly limited. A boundary portion 34 of the edge 36 and the step portion 22 is curved with a rounded corner R so that the upper side becomes the outer peripheral side. The curvature radius of the boundary portion 34 is not particularly limited and can be changed as appropriate. The curved boundary portion 34 is an intermediate position between the step portion 22 and the edge 36, and is a region that does not belong to either the step portion 22 or the edge 36.

The second portion 33 is a part curved with a rounded corner R so that the lower side becomes the outer peripheral side from the end portion of the lower side of the first portion 32. A lower surface 33a of the second portion 33 is the contact surface in contact with the upper surface 10Aa of the first component 10A. When the pressing member 20 is fixed with the fixing portions 26A, 26B, and 26C in a state where the first component 10A is not present in the base plate 2, the lower surface 33a of the second portion 33 positions lower than the upper surface 10Aa shown in FIG. 5. Therefore, when the pressing member 20 is fixed with the fixing portions 26A, 26B, and 26C in a state where the first component 10A is present in the base plate 2, the step portion 22 and the first pressing portion 23A are elastically deformed. As a result, the first pressing portion 23A can apply a downward pressing force to the first component 10A.

As shown in FIG. 6, in the regions in the X-axis direction of the pressing member 20, in regions 40A, 40B, and 40C where the first and second pressing portions 23A and 23B are not provided, the edge 36 is formed by cutting out the first portion 32. The edge 36 extends along the second direction D2. In the edge 36, the distance from the boundary portion 34 toward the positive side in the Y-axis direction is shorter than the first portion 32. The region 40A is a region between two of the first pressing portions 23A. A region 40B is the region between two of the second pressing portions 23B. A region 40C is a region between the first pressing portion 23A on the negative side in the X-axis direction and the second pressing portion 23B on the positive side in the X-axis direction.

Next, with reference to FIGS. 4 and 6, the slit 50 will be described in detail. As shown in FIG. 6, the slit 50 extends from a position corresponding to the edge 36 toward the negative side in the Y-axis direction in the region 40C between the first pressing portion 23A on the negative side in the X-axis direction and the second pressing portion 23B on the positive side in the X-axis direction. The slit 50 includes a pair of side surfaces 50a and a bottom surface 50b that is an end portion on the negative side in the Y-axis direction. The pair of side surfaces extend parallel to the Y-axis direction (see FIG. 4), the shape of the side surface 50a is not particularly limited, and the side surfaces 50a may extend so as to be inclined with respect to the Y-axis direction. The bottom surface 50b is curved in a semi-circular shape at the end portion on the negative side in the Y-axis direction of the pair of side surfaces 50a, but the shape is not particularly limited, and the bottom surface may have a substantially linear shape extending in the X-axis direction.

In the present embodiment, the slit 50 extends to and reaches the support portion 21. Here, at least a part of the bottom surface 50b of the slit 50 is located at the support portion 21. The bottom surface 50b is arranged in a region near the boundary portion 31 of the support portion 21, but may be further arranged on the negative side in the Y-axis direction. The slit 50 reaching the arbitrary position means that at least a part of the slit 50 is present at the arbitrary position.

The slit 50 may extend to and reach at least the step portion 22. That is, at least a part of the bottom surface 50b may be located at any position on the negative side of the boundary portion 34 in the Y-axis direction. The configuration where the slit 50 is formed only in the edge 36 or the configuration where the slit 50 is formed only in the edge 36 and the boundary portion 34 does not correspond to the configuration where the slit 50 reaches the step portion 22. Therefore, in the regions 40A and 40B, the configuration where the first portion 32 is cut out does not correspond to the slit 50 reaching the step portion 22. In the first direction D1, the slit 50 may extend to the support portion 21 side (the negative side in the Y-axis direction) beyond a central position CL of the step portion 22. Also, the slit 50 may reach the boundary portion 31 of the step portion 22 and the support portion 21.

The step portion 22 is a part that forms a step between the support portion 21 and the edge 36. For example, according to Japanese Patent Application No. Publication 2016-63200, a sidewall portion extends upward from a portion corresponding to the support portion 21, and a pressing portion protrudes from an upper end of the sidewall portion. In such a configuration, since the edge 36 is not present in a portion other than the pressing portion, the step portion 22 is not present. Therefore, there is no slit reaching the step portion 22.

As shown in FIG. 4, in the X-axis direction (third direction) in which the first pressing portion 23A and the second pressing portion 23B are arranged, at least a part of the slit 50 may be arranged at the same position as the fixing portion 26C. The state in which at least a part of the slit 50 is arranged at the same position as the fixing portion 26C in the X-axis direction is a state in which at least a part of the fixing portion 26C is present between a pair of reference lines SL when a pair of the reference lines SL parallel to the Y-axis direction is set with respect to both end portions (here, the side surfaces 50a on both sides) of the slit 50 in the X-axis direction. In the present embodiment, at least a part of the slit 50 is arranged in the same position as the bolt 27 of the fixing portion 26C. In addition, at least part of the slit 50 is arranged at the same position as the through hole 29 of the support portion 21 (see FIG. 6). In the X-axis direction, at least a part of the slit 50 is arranged at the same position as the gap GP between the first component 10A and the second component 10B.

The width (the size in the X-axis direction) of the slit 50 is not particularly limited. The minimum width of the slit 50 is set by the minimum size of the processing tool with which the slit 50 can be processed. The maximum width of the slit 50 is set by the separation between the first pressing portion 23A and the second pressing portion 23B. The range of the width of the slit is not particularly limited.

Next, functions and effects of the component mounting structure 100 according to the present embodiment will be described.

In the component mounting structure 100 according to the present embodiment, the pressing member 20 includes the support portion 21 fixed to the base plate 2, the step portion 22 extending the first direction D1 from the support portion 21 toward the opposite side of the base plate 2, the edge 36 extending from the end portion of the opposite side of the base plate 2 of the step portion 22 to the second direction D2 intersecting the first direction D1, the first pressing portion 23A pressing the first component 10A and protruding from the edge 36, and the second pressing portion 23B pressing the second component 10B and protruding from the edge 36. Accordingly, the pressing member 20 can support the first component 10A and the second component 10B with one member. Here, the slit 50 is provided between the first pressing portion 23A and the second pressing portion 23B, and the slit 50 reaches at least the step portion 22. Therefore, the transmission path of the displacement between the first pressing portion 23A and the second pressing portion 23B is divided by the slit 50 reaching the step portion 22. Therefore, the slit 50 can suppress interference of a displacement generated when one of the pressing portions presses one of the components with the other pressing portion. Therefore, a sufficient pressing force can be obtained in each of the pressing portions 23A and 23B without increasing the distance between the first component 10A and the second component 10B or dividing the pressing member. As described above, it is possible to suppress an increase in the size of a product and to sufficiently press a plurality of components with a small number of parts.

The slit 50 may extend to the support portion 21 beyond the central position of the step portion 22 in the first direction D1. In this case, the slit 50 divides half of the region in the first direction D1 of the step portion 22. Therefore, the transmission path of the displacement between the first pressing portion 23A and the second pressing portion 23B can be further reduced.

The slit 50 may extend to the boundary portion 31 of the step portion 22 and the support portion 21. In this case, the slit 50 divides the entire area in the first direction D1 of the step portion 22. Therefore, the transmission path of the displacement between the first pressing portion 23A and the second pressing portion 23B can be further reduced.

The slit 50 may extend to the support portion 21. In this case, the slit 50 divides the entire range of the first direction D1 in the step portion 22 and the boundary portion 31. Therefore, the transmission path of the displacement between the first pressing portion 23A and the second pressing portion 23B can be further reduced.

The support portion 21 may be fixed in the base plate 2 through the fixing portions 26A, 26B, 26C. In this case, the elastic deformation in each of the pressing portions 23A and 23B can easily occur.

In the X-axis direction (the third direction) in which the first pressing portion 23A and the second pressing portion 23B are arranged, at least a part of the slit 50 may be arranged at the same position as the fixing portion 26C. Near the fixing portion 26C, there is less transmission of displacement between the first pressing portion 23A and the second pressing portion 23B. Therefore, by setting the slit 50 and the fixing portion 26C closer to each other, the transmission path of the displacement between the first pressing portion 23A and the second pressing portion 23B can be further reduced.

In the X-axis direction in which the first pressing portion 23A and the second pressing portion 23B are arranged, at least a part of the slit 50 may be arranged at the same position as the gap GP between the first component 10A and the second component 10B. Since the pressing portion cannot be provided at the position of the gap GP, a space for arranging the pressing portion can be sufficiently secured by arranging the slit 50 near the gap GP. Thus, each of the components 10A and 10B can be supported by each of the pressing portions 23A and 23B in a well-balanced manner.

The present disclosure is not limited to the embodiments described above.

The size, arrangement, and number of components are not limited to those in the above-described embodiment, and can be changed as appropriate. In addition, in the above-described embodiment, the components are arranged only on one side in the Y-axis direction from the support portion 21, but the components may be arranged on both sides in the Y-axis direction. In this case, the pressing portion may be provided on both sides in the Y-axis direction from the support portion 21. Further, the type of the component is not particularly limited, and a component other than the core may be adopted.

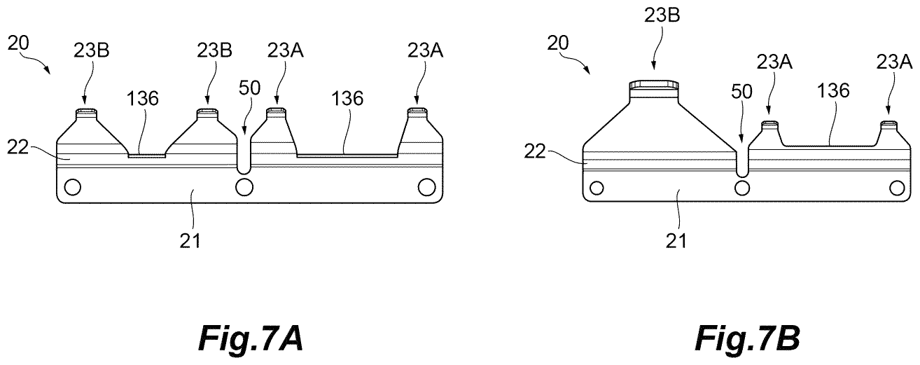

The pressing member 20 shown in FIG. 7A may be employed. Unlike the above-described embodiment, an edge 136 is provided at the position of the step portion 22 between the pressing portions 23A in the pressing member 20, and the edges 136 does not extend in the second direction. The same applies to an edge 136 between the pressing portions 23B. In this case, the slit 50 may extend to the support portion 21 beyond the central position of the step portion 22 in the first direction D1. Further, the pressing member 20 shown in FIG. 7B may be adopted. The pressing member 20 has only one second pressing portion 23B on the second pressing portion 23B side of the slit 50. The pressing member 20 may have only one first pressing portion 23A on the first pressing portion 23A side of the slit 50.

The pressing member 20 includes the support portion 21 fixing to the base plate 2, the step portion 22 extending from the support portion 21 to the first direction D1 towards the opposite side of the housing, and the first pressing portion 23A pressing the first component 10A and the second pressing portion 23B pressing the second component 10B, the first pressing portion 23A and the second pressing portion 23B extending from the end of the step portion 22 on the side opposite the housing in the second direction D2 intersecting the first direction D1. Accordingly, the pressing member 20 can support the first component 10A and the second component 10B with one member. Here, the slit 50 is provided between the first pressing portion 23A and the second pressing portion 23B, and the slit 50 extends to the support portion 21 beyond the central position of the step portion 22 in the first direction D1. Therefore, the transmission path of the displacement between the first pressing portion 23A and the second pressing portion 23B is divided by the slit 50 extending to the support portion 21 beyond the central position of the step portion 22. Therefore, the slit 50 can suppress interference of a displacement generated when one of the pressing portions presses one of the components with the other pressing portion. Therefore, a sufficient pressing force can be obtained in each of the pressing portions 23A and 23B without increasing the distance between the first component 10A and the second component 10B or dividing the pressing member 20. As described above, it is possible to suppress an increase in the size of a product and to sufficiently press a plurality of components with a small number of parts.

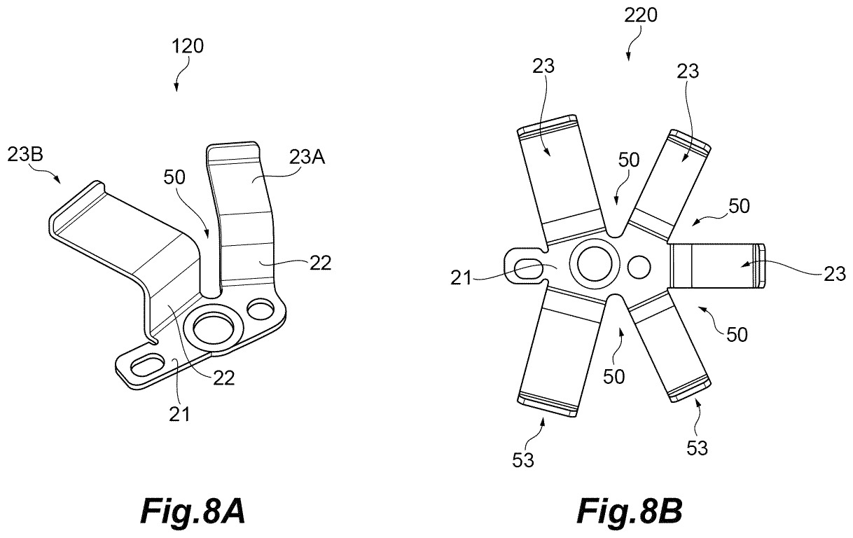

As in a pressing member 120 shown in FIG. 8A, the first pressing portion 23A and the second pressing portion 23B may extend in different directions instead of parallel directions. Each of the pressing portions 23A and 23B are formed in a truncated chevron shape in a plan view. In this case, the slit 50 may extend to the support portion 21 beyond the central position of the step portion 22 in the first direction D1. In a pressing member 220 shown in FIG. 8B, pressing portions 23 may extend not only to one side but also to the opposite side with respect to the support portion 21. The slit 50 is formed between the pressing portions 23.

What is claimed is:

1. A component mounting structure comprising:
a housing;
a first component disposed in the housing and a second component adjacent to the first component; and
a pressing member pressing the first component and the second component toward the housing,
wherein the pressing member includes a support portion fixed to the housing, a step portion extending from the support portion in a first direction toward a side opposite the housing, an edge portion extending from an end of the step portion on the side opposite the housing in a second direction intersecting the first direction, a first pressing portion pressing the first component and a second pressing portion pressing the second component, the first pressing portion and the second pressing portion protruding from the edge portions,
wherein a slit is provided between the first pressing portion and the second pressing portion, and the slit extends at least to the step portion.

2. The component mounting structure according to claim 1, wherein the slit extends in the first direction to the support portion side beyond a central position of the step portion.

3. The component mounting structure according to claim 1, wherein the slit extends to a boundary portion between the step portion and the support portion.

4. The component mounting structure according to claim 1, wherein the slit extends to the support portion.

5. The component mounting structure according to claim 1, wherein the support portion is fixed to the housing via a fixing portion.

6. The component mounting structure according to claim 5, wherein the first pressing portion and the second pressing portion are arranged in a third direction, at least part of the slit is disposed at the same position as the fixing portion in the third direction.

7. The component mounting structure according to claim 1, wherein the first pressing portion and the second pressing portion are arranged in a third direction, at least part of the slit is disposed at the same position as a gap between the first component and the second component in the third direction.

8. A component mounting structure comprising:
a housing;
a first component disposed in the housing and a second component adjacent to the first component; and
a pressing member pressing the first component and the second component toward the housing,
wherein the pressing member includes a support portion fixed to the housing, a step portion extending from the support portion in a first direction toward a side opposite the housing, a first pressing portion pressing the first component and a second pressing portion pressing the second component, the first pressing portion and the second pressing portion extending from an end of the step portion on the side opposite the housing in a second direction intersecting the first direction,
wherein a slit is provided between the first pressing portion and the second pressing portion, and the slit extends in the first direction to the support portion side beyond a central position of the step portion.
